(19) United States
(12) Patent Application Publication
(10) Pub. No.: US 2006/0199386 A1
(43) Pub. Date: Sep. 7, 2006

(54) SEMICONDUCTOR DEVICE WITH LOW-RESISTANCE INLAID COPPER/BARRIER INTERCONNECTS AND METHOD FOR MANUFACTURING THE SAME

(76) Inventors: Jim-Jey Huang, Tainan Hsien (TW); Chih-Chien Liu, Taipei City (TW); Feng-Yu Hsu, Tainan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/164,847

(22) Filed: Dec. 7, 2005

Related U.S. Application Data
(60) Provisional application No. 60/593,242, filed on Dec. 27, 2004.

(51) Int. Cl. H01L 21/44

(52) U.S. Cl. 438/687

(57) ABSTRACT

An inlaid copper/barrier interconnect includes a semiconductor substrate; a carbon-doped oxide (CDO) dielectric layer disposed over the semiconductor substrate; a damascene recess etched into the CDO dielectric layer; an alpha-phase tantalum (α-Ta) single-layer barrier sputter deposited on sidewall and bottom of the damascene recess; and a conductive layer deposited directly on the alpha-phase tantalum single-layer barrier, wherein the conductive layer fills the damascene recess. According to one preferred embodiment, the alpha-phase tantalum single-layer barrier has a resistivity of about 25 μΩ-cm.

### CROSS REFERENCE TO RELATED APPLICATIONS

This application claims the benefit of U.S. provisional application No. 60/593,242, filed Dec. 27, 2004.

### BACKGROUND OF THE INVENTION

1. Field of the Invention

The present invention relates to a method for manufacturing semiconductor device with low-resistance inlaid copper/barrier interconnects and, more particularly, to a method for physical vapor depositing a low-resistivity alpha-phase tantalum (α-Ta) film directly on the surface of a carbon-doped oxide (CDO) dielectric layer without an underlying tantalum nitride (TaN) base layer.

2. Description of the Prior Art

To meet the need of high integration and high processing speed of integrated circuits of nano-scale generations, copper interconnect technology has become an effective solution. Copper is approximately 40% lower in resistivity than aluminum and has fewer reliability concerns such as electromigration. Copper interconnect technology, by and large, has been implemented employing damascene techniques, wherein an inter-layer dielectric (ILD) layer, such as a carbon-doped silicon oxide layer (also referred to as carbon-doped oxide or CDO) or other low-k (k<3.0) dielectrics, is formed over an underlying metal features, e.g., copper or copper alloy features with a silicon nitride capping layer. A damascene opening, e.g., via hole, trench, or dual damascene opening, is then formed in the ILD layer. A barrier layer and optional seed layer are then deposited, followed by copper deposition, as by electrodeposition or electroless deposition.

One concern with the use of copper as interconnect material is its diffusion property. To prevent copper from diffusing into the ILD layer, the copper core of the damascene structure is typically encapsulated with a diffusion barrier metal. Typical diffusion barrier metals include tantalum (Ta), tantalum nitride (TaN), titanium nitride (TiN) or titanium (Ti) for encapsulating copper core. Among these barrier materials, tantalum is more prevalent than others in the semiconductor industry because of its relatively higher thermal reliability and ability to prevent copper diffusion. As the line width shrinks to 65 nm or 45 nm node, it is desirable to form a diffusion barrier with reduced thickness and resistance, while maintaining the ability to prevent copper diffusion.

As known in the art, Ta and TaN are typically deposited by physical vapor deposition (PVD) techniques. Also, it has been known that tantalum exists in two crystalline phases, i.e., α phase and β phase. The α-phase Ta (hereinafter referred to as α-Ta) exhibits a relatively low resistivity about 25 μΩ-cm, while the β-phase Ta (hereinafter referred to as β-Ta) exhibits a relatively high resistivity of about 200 βΩ-cm. Unfortunately, the β-Ta forms readily in a conventional PVD process.

One approach to forming α-Ta includes first forming a seed layer or base layer of tantalum doped with nitrogen (TaN) on an ILD layer by sputtering in a nitrogen containing ambient, and then depositing a layer of tantalum (α-Ta) on the seed layer in a nitrogen free ambient, which is disclosed in U.S. Pat. No. 5,281,485 by Colgan et al. filed Jan. 15, 1993. This method has a drawback in that a high-resistivity TaN base layer of at least 20 angstroms is required to form α-Ta, and the adhesion between the low-k materials and the TaN base layer needs to be enhanced.

Another approach to forming α-Ta is employing a high substrate temperature exceeding 400° C. during the PVD process. However, it is not practical because processing substrate temperatures above 400° C. are typically not compatible with device fabrication.

The high resistivity of TaN and β-Ta manifestly adversely impact circuit speed. This high resistively becomes increasingly important as the density of interconnects increases and the wire size decreases with 90 nanometer and sub 90-nanometer groundrules. Accordingly, there exists a need for low-resistance interconnects, particularly copper and copper alloy interconnects formed in/on low-k materials, particularly in/on carbon-doped oxide (CDO) low-k dielectric used by most manufacturers at 90 and 65 nm processes.

### SUMMARY OF THE INVENTION

It is the primary object of the present invention to provide a PVD method for forming a low-resistivity, substantially pure alpha-phase tantalum (α-Ta) barrier that is deposited directly on the pre-treated surface of a carbon-doped oxide (CDO) dielectric layer without employing a tantalum nitride (TaN) base layer in order to improve the resistance and adhesion of the inlaid copper/barrier interconnects of integrated circuit devices.

According to the claimed invention, a method for manufacturing semiconductor device with low-resistance inlaid copper/barrier interconnects is disclosed. The method includes the steps of:

(a) providing a substrate;

(b) depositing a carbon-doped oxide (CDO) dielectric layer over the substrate;

(c) etching away a portion of the CDO dielectric layer to form a damascene recess therein;

(d) plasma treating surface of the CDO dielectric layer in a reductive plasma ambient for a pre-selected time period;

(e) sputter depositing alpha-phase tantalum (α-Ta) barrier onto the plasma-treated surface of the CDO oxide; and

(f) filling the damascene recess with a conductive layer deposited directly on the alpha-phase tantalum barrier.

From one aspect of this invention, an inlaid copper/barrier interconnect is provided. The inlaid copper/barrier interconnect includes a semiconductor substrate; a carbon-doped oxide (CDO) dielectric layer disposed over the semiconductor substrate; a damascene recess etched into the CDO dielectric layer; an alpha-phase tantalum (α-Ta) single-layer barrier sputter deposited on sidewall and bottom of the damascene recess; and a conductive layer deposited directly on the alpha-phase tantalum single-layer barrier, wherein the conductive layer fills the damascene recess.

From another aspect of this invention, a method for manufacturing low-resistance inlaid copper/barrier interconnect is provided. The method includes:

(a) providing a substrate;

(b) depositing a carbon-doped oxide (CDO) dielectric layer over the substrate;

(c) etching away a portion of the CDO dielectric layer to form a damascene recess therein;

(d) plasma treating surface of the CDO dielectric layer in a reductive plasma ambient for a pre-selected time period;

(e) sputter depositing a first alpha-phase tantalum (α-Ta) layer onto the plasma-treated surface of the CDO oxide;

(f) depositing a tantalum nitride (TaN) layer on the first α-Ta layer;

(g) depositing a second α-Ta layer on the TaN layer; and

(h) filling the damascene recess with a conductive layer deposited directly on the second α-Ta layer.

From another aspect of this invention, an inlaid copper/barrier interconnect includes a semiconductor substrate; a carbon-doped oxide (CDO) dielectric layer disposed over the semiconductor substrate; a damascene recess etched into the CDO dielectric layer; an α-Ta/TaN/α-Ta composite barrier sputter deposited on sidewall and bottom of the damascene recess; and a conductive layer deposited directly on theo α-Ta/TaN/α-Ta composite barrier, wherein the conductive layer fills the damascene recess.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-6 are schematic, cross-sectional diagrams illustrating the process of forming a copper dual damascene for an integrated circuit in accordance with the preferred embodiment of this invention;

FIG. 7 is a flow chart demonstrating the salient steps of this invention;

FIG. 8 is a plot demonstrating the time effect on the formation of low-resistivity α-Ta layer on the plasma-treated surface of CDO dielectric in accordance with the preferred embodiment of this invention; and

FIG. 9 is an experimental plot demonstrating the carbon effect on the ILD layer for the formation of low-resistivity α-Ta layer.

### DETAILED DESCRIPTION

This invention is directed to a method for physical vapor depositing a low-resistivity α-Ta barrier directly on the surface of a carbon-doped oxide (CDO) dielectric layer, such as SiOCH, SiON, SiCN or SiC, without employing a TaN base layer. As previously mentioned, with the line width shrinks to 65 nm or 45 nm node, it is desirable to form a diffusion barrier with reduced resistance, while maintaining the ability to prevent copper diffusion. By directly depositing a low-resistivity α-Ta single-layer barrier on the interior surface of a dual damascene recess instead of TaN/Ta, the resistance of the copper interconnect can be reduced, thereby improving the speed of the integrated circuits. It is another advantage of the invention that the adhesion between the barrier and the underlying copper wiring (lower level metal) is improved with the use of pure α-Ta as a barrier material.

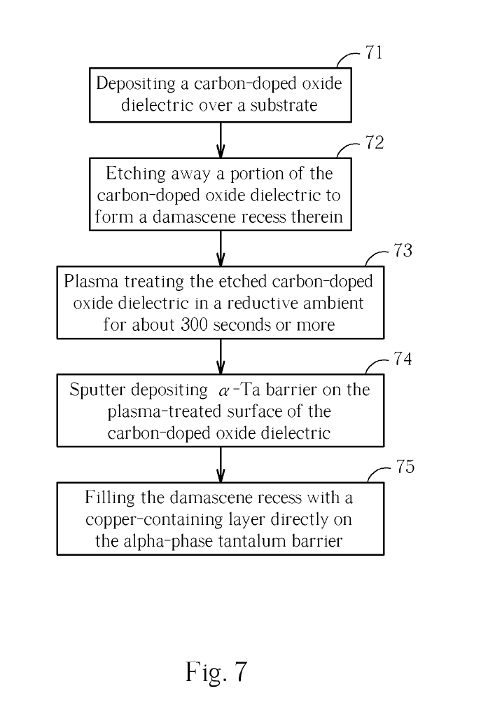

Please initially refer to FIG. 7. FIG. 7 is a flow chart demonstrating salient steps of the method for directly depositing α-Ta diffusion barrier on the surface of a CDO dielectric layer according to this invention. As shown in FIG. 7, the present invention method begins with the deposition of a CDO dielectric layer over a substrate (Step 71). The substrate is typically a single crystalline silicon substrate. However, other substrate can be used such as germanium, gallium arsenide, germanium silicon, silicon-on-insulator (SOI) substrates, and the like.

After the deposition of the CDO dielectric layer, a lithographic process is performed to form a photoresist pattern having an opening exposing a portion of the underlying CDO dielectric layer. The exposed portion of the underlying CDO dielectric layer is then etched away by using the photoresist pattern as an etching hard mask, thereby forming a damascene recess in the CDO dielectric layer (Step 72).

After removing the photoresist pattern, the surface of the CDO dielectric layer is subjected to a plasma treatment in a reductive ambient such as 1% wt.-25% wt., preferably 5% wt., hydrogen carried by helium (5% H₂/He) for about 300 seconds or more (Step 73). Subsequently, a physical vapor deposition (PVD) process is performed to sputter deposit α-Ta layer onto the plasma treated surface of the CDO dielectric layer (Step 74). The damascene recess is then filled with a copper-containing layer (Step 75). The copper-containing layer is formed directly on the α-Ta layer. A copper seed layer may be formed on the α-Ta layer prior to the deposition of the copper-containing layer.

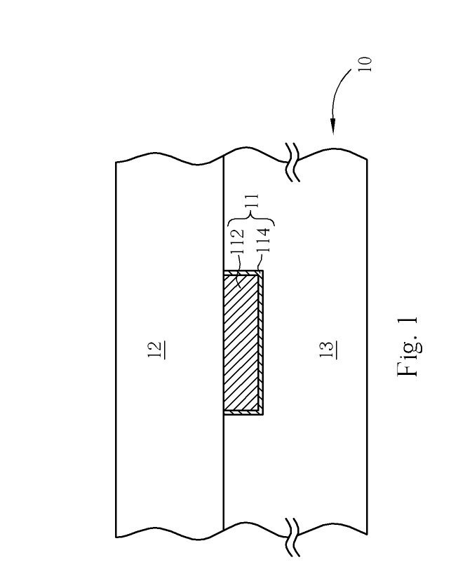

The invention can be further understood with reference to FIGS. 1-6. FIGS. 1-6 are schematic, cross-sectional diagrams illustrating the process of forming a copper dual damascene for an integrated circuit in accordance with the preferred embodiment of this invention.

Referring to FIG. 1, an exemplary portion of semiconductor substrate 10 that is germane to this invention is shown having a metal layer 11, which is covered by an inter-layer dielectric (ILD) layer 12. Although not specifically illustrated in FIG. 1, a silicon nitride or silicon carbide capping layer may be interposed between the ILD layer 12 and the metal layer 11. Metal layer 11 is representative of one of the metal layers in a multiple metal level semiconductor device.

According to the preferred embodiment, the ILD layer 12 is formed from carbon-containing low k materials such as carbon-doped oxide (CDO) dielectric. The CDO dielectric can be formed by conventional plasma-enhanced chemical vapor deposition (PECVD) techniques. It is appreciated that other carbon-rich dielectric materials can be utilized for ILD layer 12. Further, the ILD layer 12 can be a composite dielectric layer with or without an intermediate etching stop layer.

Generally, metal 11, which comprises a copper core 112 and a diffusion barrier 114 encapsulating the copper core 112, is inlaid into an underlying dielectric material 13, but what comprises the underlying material 13 is not critical to the understanding of the practice of the present invention. Also, it is understood that structure 10 is only a portion of many structures present on a semiconductor wafer.

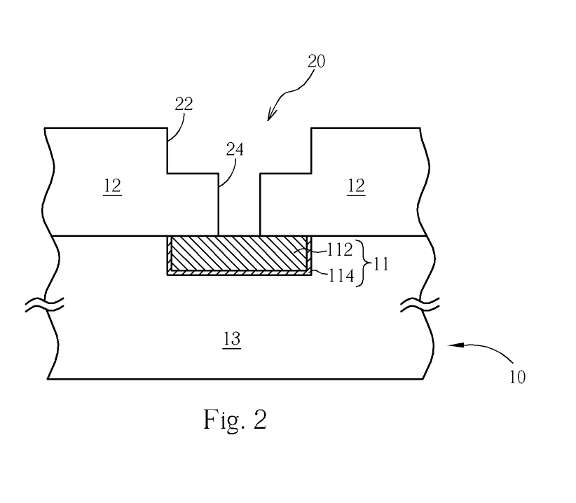

Referring to FIG. 2, by the use of a well-known process, a dual damascene recess 20 comprising a trench opening 22 and a via opening 24 is made in ILD 12 in order to provide a pathway to metal layer 11. It is appreciated that the dual damascene recess 20 of FIG. 2 can be fabricated from a variety of known processes such as trench-first, via-first or partial-via dual damascene methods. It is also appreciated that etching process for the formation of the dual damascene recess 20 be optimized so that the etch process stops when the copper core 112 is reached.

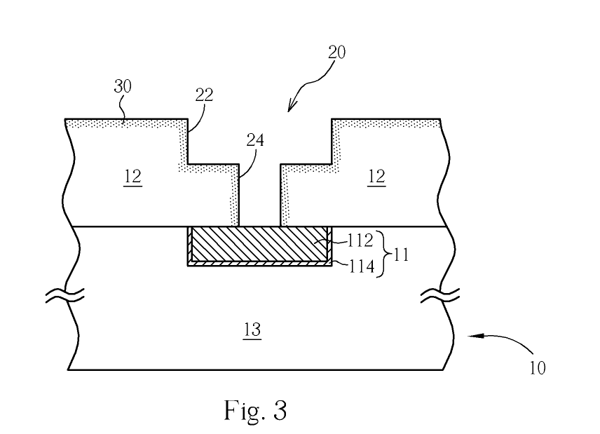

Referring to FIG. 3, the surface of the ILD 12 including the sidewalls of the dual damascene recess 20 are subjected to 5% H₂/He, H₂/N₂ or H₂/Ar plasma treatment for a time period exceeding 60 seconds, preferably exceeding 200 seconds, and more preferably exceeding 300 seconds. This plasma treatment may be carried out in a PVD tool such as Endura series available from Applied Materials Corporation, but not limited thereto. After the plasma treatment, a surface active layer 30 having decreased Si—O bonding and increased Si—C bonding is created.

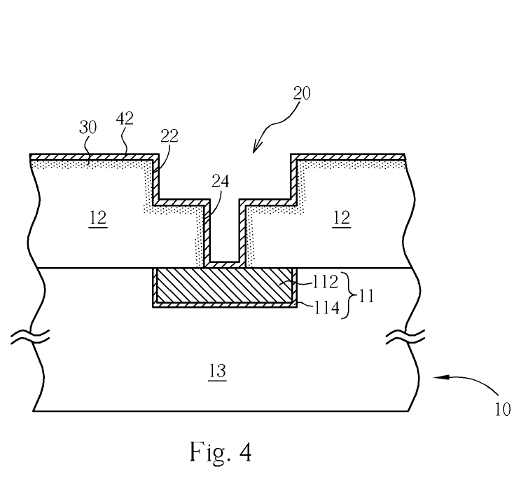

Referring to FIG. 4, a low-resistivity α-Ta layer 42 is then in-situ deposited onto the surface active layer 30 by using, for example, conventional DC magnetron plasma deposition methods. The thickness of the α-Ta layer 42 ranges between 10-100 angstroms, preferably 25-50 angstroms. According to the experimental results of X-ray diffraction (XRD) scan test, it is unexpectedly found that in a case that the plasma treatment time exceeds 300 seconds, the resultant α-Ta layer 42 contains substantially pure α phase having <110> crystalline orientation in the majority and <211> crystalline orientation without detectable β-Ta. It is believed that the formation of the surface active layer 30 having increased Si—C bonding facilitates the formation of the low-resistivity, pure α-Ta layer 42.

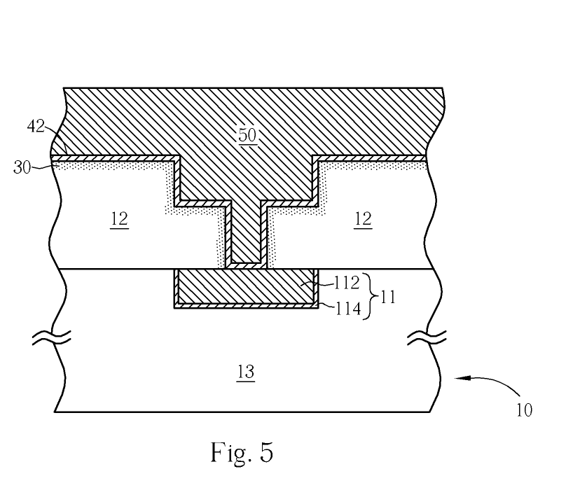

Referring to FIG. 5, copper deposition process such as conventional electrodeposition or electroless deposition methods is performed to fill the dual damascene recess 20 with copper layer or copper alloys 50. The copper layer 50 is formed directly on the α-Ta layer 42. If necessary, a copper seed layer (not shown) may be formed on the α-Ta layer 42 prior to the deposition of copper layer 50.

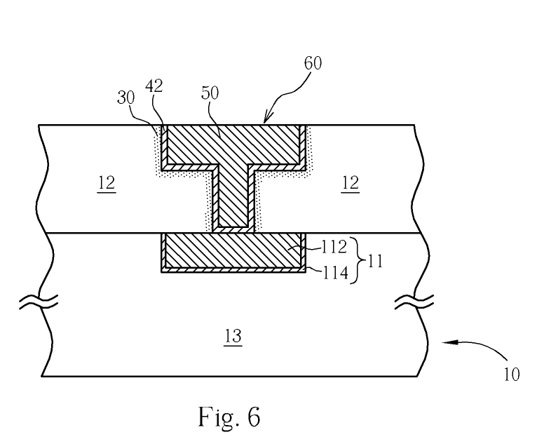

Referring to FIG. 6, a conventional chemical mechanical polishing (CMP) process is carried out to remove the excess copper layer 50 outside the dual damascene recess 20. The CMP process typically comprises two steps. The first polish step is polishing the bulk copper layer 50 by using a first polishing pad such as IC 1000 or IC 1010 mounted on a first platen. The first polish step stops on the α-Ta layer 42. The second polish step is polishing the α-Ta layer 42 by using a second polishing pad such as Politex™ mounted on a second platen. The second polish step stops on the ILD layer 12. The second polish step may be followed by an over-polish step or oxide touch up to make sure that any residual copper is removed. After the CMP, an inlaid copper dual damascene structure 60 is produced. Thereafter, a silicon nitride or silicon carbide capping layer (not shown) may be formed on the copper dual damascene structure 60.

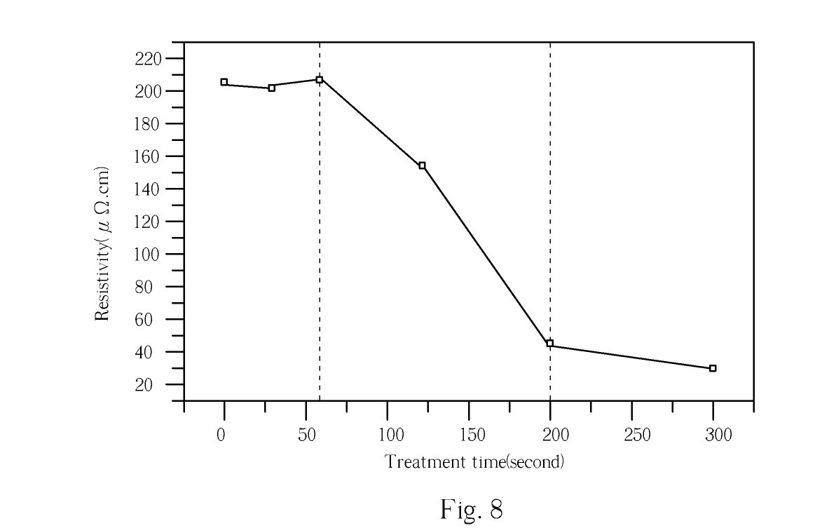

According to this invention, the time of the plasma treatment prior to the sputter deposition of α-Ta layer is critical. FIG. 8 is an experimental plot demonstrating the time effect on the formation of low-resistivity α-Ta layer on the plasma-treated surface of CDO dielectric. As shown in FIG. 8, it is surprisingly found that after a 200-second 5% H₂/He, H₂/N₂ or H₂/Ar plasma treatment, a resistivity of about 40 μΩ-cm of the α-Ta layer 42 is observed, and after a 300-second 5% H₂/He plasma treatment, a resistivity of about 25 μΩ-cm of the α-Ta layer 42 can be obtained.

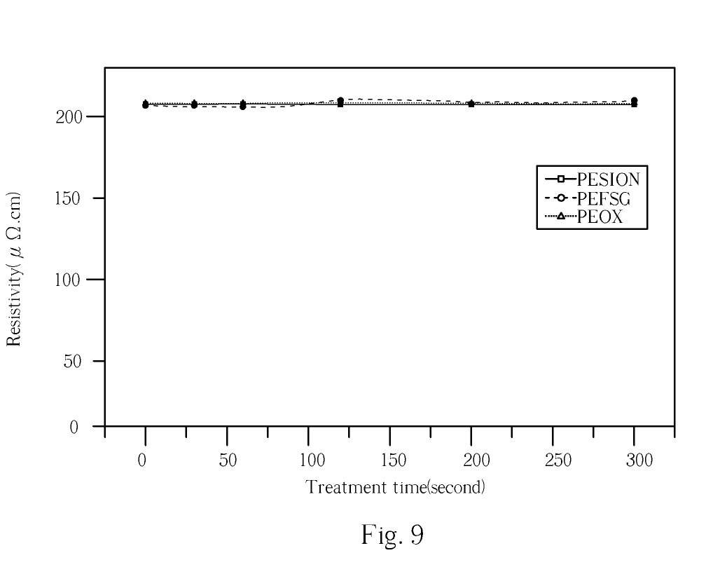

Referring to FIG. 9, an experimental plot demonstrating the carbon effect on the ILD layer 12 for the formation of low-resistivity α-Ta layer is illustrated. Some PECVD oxide based dielectrics including FSG (designated as PEFSG in FIG. 9), plasma-enhanced oxide (PEOX) and plasma-enhanced silicon oxy-nitride (designated as PESION in FIG. 9) are applied in comparison with the CDO dielectric. These chosen non-carbon doped oxide based dielectrics are treated with 5% H₂/He, H₂/N₂ or H₂/Ar plasma respectively for different time periods ranging from 0 second to 300 seconds. A conventional PVD sputter is then carried out to deposit a tantalum layer on the plasma treated oxide based dielectrics. The resistivity of the resultant tantalum layer is measured. It is unexpectedly found that β-Ta is dominant in the resultant tantalum layer regardless of the plasma treatment time when these non-carbon doped oxide based dielectrics are used as an ILD layer. This experimental result confirms that the formation of the surface active layer 30 having increased Si—C bonding facilitates the formation of the low-resistivity, pure α-Ta layer 42.

According to another preferred embodiment of this invention, after the deposition of the α-Ta layer (first α-Ta layer), a TaN layer is deposited onto the α-Ta layer. A second α-Ta layer is then deposited onto the TaN layer, thereby forming an α-Ta/TaN/α-Ta composite barrier. The copper-containing layer is formed on the second α-Ta layer of the α-Ta/TaN/α-Ta composite barrier.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for manufacturing semiconductor device with low-resistance inlaid copper/barrier interconnects, comprising:
providing a substrate;
depositing a dielectric layer over the substrate;
etching away a portion of the dielectric layer to form a damascene recess therein;
plasma treating surface of the dielectric layer in a reductive plasma ambient for a pre-selected time period;
sputter depositing alpha-phase tantalum (α-Ta) barrier onto the plasma-treated surface of the dielectric layer; and
filling the damascene recess with a conductive layer deposited directly on the alpha-phase tantalum barrier.

2. The method according to claim 1 wherein the dielectric layer is a carbon-doped oxide (CDO) dielectric layer.

3. The method according to claim 2 wherein the CDO dielectric layer comprises SiOCH, SiON, SiCN or SiC.

4. The method according to claim 1 wherein the reductive plasma ambient comprises 5% H₂/He plasma, H₂/N₂ or H₂/Ar plasma.

5. The method according to claim 1 wherein the alpha-phase tantalum barrier has a resistivity of less than 40 μΩ-cm.

6. The method according to claim 1 wherein after filling the damascene recess with the conductive layer, the method further comprising:
performing a chemical mechanical polishing (CMP) process to remove the conductive layer outside the damascene recess.

7. The method according to claim 1 wherein the conductive layer comprises copper and copper alloys.

8. The method according to claim 1 wherein the pre-selected time period is longer than 60 seconds.

9. The method according to claim 1 wherein the pre-selected time period is about 300 seconds.

10. An inlaid copper/barrier interconnect, comprising:
a semiconductor substrate;
a dielectric layer disposed over the semiconductor substrate;
a damascene recess etched into the dielectric layer;
an alpha-phase tantalum (α-Ta) single-layer barrier sputter deposited on sidewall and bottom of the damascene recess; and
a conductive layer deposited directly on the alpha-phase tantalum single-layer barrier, wherein the conductive layer fills the damascene recess.

11. The inlaid copper/barrier interconnect according to claim 10 wherein the dielectric layer is a carbon-doped oxide (CDO) dielectric layer.

12. The inlaid copper/barrier interconnect according to claim 11 wherein the CDO dielectric layer comprises SiOCH, SiON, SiCN or SiC.

13. The inlaid copper/barrier interconnect according to claim 10 wherein the alpha-phase tantalum single-layer barrier has a resistivity of less than 40 μΩ-cm.

14. The inlaid copper/barrier interconnect according to claim 10 wherein the alpha-phase tantalum single-layer barrier has a resistivity of about 25 μμ-cm.

15. The inlaid copper/barrier interconnect according to claim 10 wherein the conductive layer comprises copper and copper alloys.

16. The inlaid copper/barrier interconnect according to claim 10 wherein the alpha-phase tantalum single-layer barrier has a thickness of 10-100 angstroms.

17. A method for manufacturing low-resistance inlaid copper/barrier interconnect, comprising:
providing a substrate;
depositing a dielectric layer over the substrate;
etching away a portion of the dielectric layer to form a damascene recess therein;
plasma treating surface of the dielectric layer in a reductive plasma ambient for a pre-selected time period;
sputter depositing a first alpha-phase tantalum (α-Ta) layer onto the plasma-treated surface of the dielectric layer;
depositing a tantalum nitride (TaN) layer on the first α-Ta layer;
depositing a second α-Ta layer on the TaN layer; and
filling the damascene recess with a conductive layer deposited directly on the second α-Ta layer.

18. The method according to claim 17 wherein the dielectric layer is a carbon-doped oxide (CDO) dielectric layer.

19. The method according to claim 18 wherein the CDO dielectric layer comprises SiOCH, SiON, SiCN or SiC.

20. The method according to claim 17 wherein the reductive plasma ambient comprises 5% H₂/He plasma, H₂/N₂ or H₂/Ar plasma.

21. The method according to claim 17 wherein the alpha-phase tantalum barrier has a resistivity of less than 40 μΩ-cm.

22. The method according to claim 17 wherein after filling the damascene recess with the conductive layer, the method further comprising:
performing a chemical mechanical polishing (CMP) process to remove the conductive layer outside the damascene recess.

23. The method according to claim 17 wherein the conductive layer comprises copper and copper alloys.

24. The method according to claim 17 wherein the pre-selected time period is longer than 60 seconds.

25. The method according to claim 17 wherein the pre-selected time period is about 300 seconds.

26. An inlaid copper/barrier interconnect, comprising:
a semiconductor substrate;
a dielectric layer disposed over the semiconductor substrate;
a damascene recess etched into the dielectric layer;
an alpha-phase tantalum (α-Ta)/tantalum nitride (TaN)/alpha-phase tantalum (α-Ta) composite barrier on sidewall and bottom of the damascene recess; and
a conductive layer deposited directly on the α-Ta/TaN/α-Ta composite barrier, wherein the conductive layer fills the damascene recess.

27. The inlaid copper/barrier interconnect according to claim 26 wherein the dielectric layer is a carbon-doped oxide (CDO) dielectric layer.

28. The inlaid copper/barrier interconnect according to claim 27 wherein the CDO dielectric layer comprises SiOCH, SiON, SiCN or SiC.

29. The inlaid copper/barrier interconnect according to claim 26 wherein the conductive layer comprises copper and copper alloys.

30. The inlaid copper/barrier interconnect according to claim 26 wherein the α-Ta has a resistivity of less than 40 μΩ-cm.
